(19) United States
(12) Patent Application Publication
(10) Pub. No.: US 2014/0376295 A1
(43) Pub. Date: Dec. 25, 2014

(54) MEMORY DEVICE AND SYSTEM INCLUDING THE SAME

(71) Applicant: SK HYNIX INC., Icheon (KR)

(72) Inventors: Jong Hoon OH, Seongnam (KR); Suk Joo MYUNG, Guri (KR); June Hyung AHN, Icheon (KR)

(73) Assignee: SK HYNIX INC., Icheon (KR)

(21) Appl. No.: 14/077,752

(22) Filed: Nov. 12, 2013

(30) Foreign Application Priority Data
Jun. 19, 2013 (KR) 10-2013-0070058

(51) Int. Cl. G11C 29/52

(52) U.S. Cl. CPC G11C 29/52
USPC 365/51

(57) ABSTRACT

A memory device includes a plurality of first dies stacked on a substrate, and a second die configured to perform an error correction operation on data written in the first dies and data read out from the first dies.

### CROSS-REFERENCES TO RELATED APPLICATION

The present application claims priority to Korean patent application number 10-2013-0070058, filed on 19 Jun. 2013, which is incorporated by reference herein in its entirety.

### BACKGROUND OF THE INVENTION

1. Technical Field

The inventive concept relates to a memory device, and more particularly, to a memory device including a die having an error correction unit and a system including the same.

2. Related Art

Memory devices for data storage have been widely used in electronic devices. With demand on miniaturization and high speed of the electronic devices, the memory devices require the same characteristics.

With miniaturization and high speed of the memory devices, there is concern about degradation in reliability for data stored in the memory devices, and thus a separate unit for checking error of data is used.

In data input and output in the semiconductor memory devices including a plurality of stacked dies, it is desirable to develop technology for minimizing burden of the core dies configured to process a parity bit in addition to a separate die configured to manage the parity bit for checking an error of data in the core dies.

### SUMMARY

One or more embodiments are provided for a semiconductor memory device suitable for a portable apparatus with a high speed operation by improving operation speed thereof.

According to an aspect of an embodiment, there is a memory device. The memory device may include: a plurality of first dies stacked on a substrate; and a second die configured to perform error correction on write data written to the first dies and read data read out from the plurality of first dies.

In some embodiments, the first die may correspond to a core die including a memory, and the second die may correspond to a logic die.

In another embodiment, the second die may correspond to a parity die configured to perform an error correction. In another embodiment, the second die may be a logic die including control logic circuitry.

The second die may include a memory storing an error correction code for checking whether or not the read data includes an error, and a controller configured to generate the error correction code based on the write data and store the error correction cord in the memory and to read out the error correction code corresponding to the read data from the memory and check whether or not the read data is erroneous.

The controller may include an input/output unit configured to read out the read data from the first stacked dies and reads out the error correction code from the memory, based on a read command and a read address provided from the outside, and to write the write data based on a write command, the write data, and a write address, and write the error correction code generated based on the write data in the memory, and an error correction unit configured to check whether or not the read data is erroneous based on the read error correction code, and generate the error correction code based on the write data.

The memory device may further include a logic die stacked below the plurality of first dies and configured to perform logic operations for data exchanged between the first dies and a central processing device.

The logic die is disposed between the second die and the substrate.

The plurality of first dies may include dynamic random access memory (DRAM) devices.

The plurality of first dies may be electrically coupled to one another through at least one through via.

The second die may include an interface unit configured to perform an interfacing operation on at least one among a control signal, data stored in the plurality of first dies, an update signal, a status signal, and a training signal.

According to an aspect of an embodiment, there is a system. The system may include: a central processing device configured to provide an operation command; and a memory device configured to receive the operation command from the central processing device through a channel to perform a read operation and a write operation, and perform an error correction operation in the read and write operations. The memory device may include a plurality of first dies stacked on a substrate; and a second die configured to perform an error correction operation on write data written in the first dies and read data read out from the first dies.

The memory device may include a memory cell array configured to receive data and write the data. The memory device may include a wide input/output (I/O) type dynamic random access memory (DRAM) device.

The central processing device and the memory device may be mounted on the substrate.

The channel may be coupled between an interface unit included in the second die and an interface unit included in the central processing device.

The interface units may be physical control interfaces.

The central processing device includes a graphic processing unit (GPU) or a central processing unit (CPU).

The memory device may further include a plurality of memory devices disposed on the substrate around the central processing device.

According to an aspect of an embodiment, there is a system. The system may include: a central processing device configured to provide an operation command and perform an error correction operation on data; and a memory device configured to receive data and an error correction code from the central processing device in response a write command to write the data and to write the error correction code, or configured to read out data and an error correction code in response to a read command and provide the read data and error correction code to the central processing device. The memory device may include a first die configured to store the data and a second die including a memory configured to store the error correction code. The error correction code may be written in the memory or read out from the memory based on an address which the data is written in or read out from.

According to an aspect of an embodiment, there is a semiconductor device. The semiconductor device includes a substrate, a plurality of memory dies, a second die, a central processing device, and a memory. The plurality of memory dies and the second die are stacked on the substrate. The central processing device communicates with the memory dies through the second die. The memory disposed on the second die and store error correction information associated with data stored in the plurality of memory dies.

For example, the second die is a logic die including a controller circuit with a register. The register may temporarily store data exchanged between the plurality of memory dies and the central processing device.

In some embodiments, the semiconductor device may further include a logic die stacked with the plurality of memory dies and the second die. For example, error correction may be performed during a waiting time in a time cycle synchronized between an interface unit and the central processing device.

Aspects of the inventive concept should not be limited by the above description, and other unmentioned aspects will be clearly understood by one of ordinary skill in the art from embodiments described herein.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a plan view illustrating a system according to an embodiment of the present invention;

FIG. 2 is a cross-sectional view illustrating the system according to an embodiment of the present invention, taken along line I-I′ of FIG. 1;

FIGS. 3 and 4 are cross-sectional views illustrating memory devices according to embodiments;

FIGS. 5 and 6 are block diagrams illustrating systems according to embodiments including the memory device of FIG. 3; and

FIG. 7 is a block diagram illustrating a system including the memory device of FIG. 4.

### DETAILED DESCRIPTION

Hereinafter, embodiments will be described in greater detail with reference to the accompanying drawings.

Embodiments are described herein with reference to cross-sectional illustrations that are schematic illustrations of embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but may be to include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present. Although certain features are described as being “units,” those features may be implemented as physical circuits in a semiconductor.

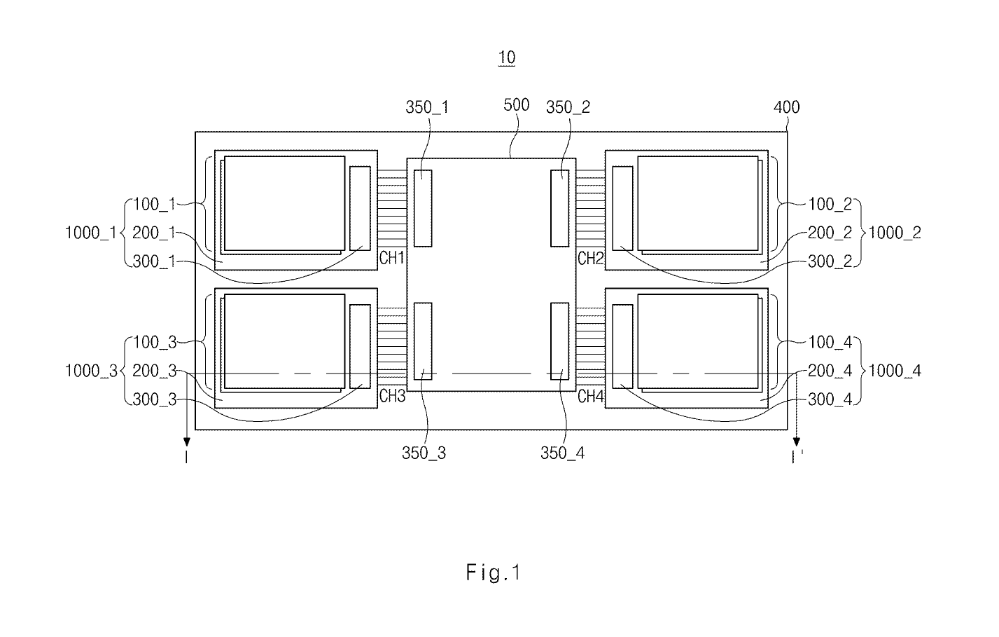

FIG. 1 is a plan view illustrating a system 10 according to an embodiment of the present invention.

Referring to FIG. 1, the system 10 according to an embodiment of the present invention may include stacked core dies 100_1, 100_2, 100_3, and 100_4, logic dies 200_1, 200-2, 200_3, and 200_4, interface units 300_1, 300_2, 300_3, 300_4, 350_1, 350_2, 350_3, and 350_4, a substrate 400, and a central processing device 500. The system 10 may be implemented in a package type device.

The central processing device 500 may be mounted on the substrate 400. The central processing device 500 may be a device including a host controller, include various processors such as a central processing unit (CPU) or a graphic processor unit (GPU), and control an overall operation of the system 10.

The system 10 according to an embodiment of the present invention may be a wide input/output (I/O) type system, and the central processing device 500 may be coupled to respective channels CH1, CH2, CH3, and CH4 through four second interface units 350_1, 350_2, 350_3, and 350_4.

The logic dies 200_1, 200_2, 200_3, and 200_4, first interface units 300_1, 300_2, 300_3, and 300_4, and the stacked core dies 100_1, 100_2, 100_3, and 100_4 may constitute memory devices 1000_1, 1000_2, 1000_3, and 1000_4.

Referring to FIG. 1, the central processing device 500 may be located in a central portion of the substrate 400, and four memory devices 1000_1, 1000_2, 1000_3, and 1000_4 are disposed to surround the central processing device 500. The memory devices 1000_1, 1000_2, 1000_3, and 1000_4 may be coupled to the central processing device 500 through the channels CH1, CH2, CH3, and CH4 between the first interface units 300_1, 300_2, 300_3, and 300_4 and the second interface units 350_1, 350_2, 350_3, and 350_4.

The first and second interface units 300_1, 300_2, 300_3, and 300_4 and 350_1, 350_2, 350_3, and 350_4 may perform an interfacing operation of adjusting a transfer rate, a data modulation and demodulation method, and the like in a suitable form to transmit and receive signals between the central processing device 400 and the memory devices 1000_1, 1000_2, 1000_3, and 1000_4. Further, the first and second interface units 300_1, 300_2, 300_3, and 300_4 and 350_1, 350_2, 350_3, and 350_4 may perform a control interface operation, a write and read data interface operation, an update interface operation, a status interface operation, and a training interface operation. In an embodiment, the first and second interface units 300_1, 300_2, 300_3, and 300_4, and 350_1, 350_2, 350_3, and 350_4 may be physical control interfaces (PHY).

FIG. 1 illustrates that the memory devices 1000_1, 1000_2, 1000_3, and 1000_4 are arranged to surround the central processing device 500, but this is an arrangement so as to effectively couple the central processing device 500 and a plurality of memory devices 1000_1, 1000_2, 1000_3, and 1000_4. In an embodiment, the central processing device 500 and the plurality of memory devices 1000_1, 1000_2, 1000_3, and 1000_4 may be arranged on the substrate 400 in various manners.

The memory devices 1000_1, 1000_2, 1000_3, and 1000_4 may have different interfacing methods and may transmit and receive data and the like to and from the central processing unit 500. Communication between the memory devices 1000_1, 1000_2, 1000_3, and 1000_4 and the central processing device 500 may include transmitting and receiving data through the channels CH1, CH2, CH3, and CH4 configured to couple the memory devices and the central processing unit.

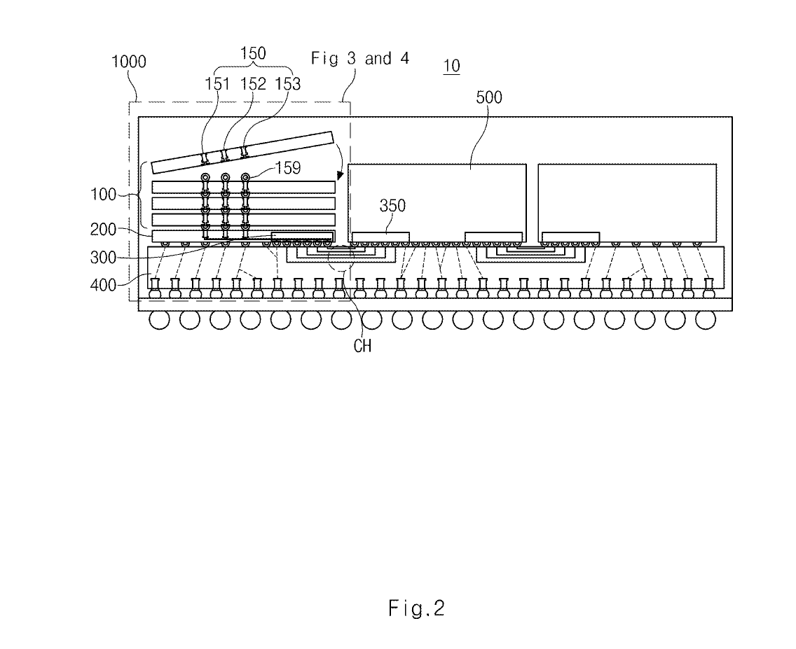

FIG. 2 is a cross-sectional view of the system according to an embodiment of the present invention taken along line I-I′ of FIG. 1.

Referring to FIG. 2, each of the memory devices 1000_1, 1000_2, 1000_3, and 1000_4 may include the stacked core dies 100, the logic die 200, and the first interface unit 300, and the stacked core dies 100 may be electrically coupled through a through via 150 vertically penetrating an inside of the stacked core dies 100. In FIG. 1, a configuration in which four memory devices 1000_1, 1000_2, 1000_3, and 1000_4 are coupled has been illustrated. However, for the sake of clarity, FIG. 2 only shows a single memory device 1000 which may represent any of the memory devices 1000_1 to 1000_4 shown in FIG. 1.

The stacked core dies 100 and the logic die 200 may be coupled to the substrate 400 by electrical connections 159. In an embodiment, electrical connection 159 may be a solder ball, a micro bump, or the like. The stacked core dies 100 and logic die 200 are stacked on the substrate to be packaged.

In this way, when the stacked core dies 100 in which a plurality of core dies are stacked transmits and receives data, an error bit mechanism may be used to determine data reliability and a transmission error. The error bit mechanism may use an error correction code, for example, a parity bit.

To perform error correction using the parity bit, an additional circuit configured to process the parity bit is used. When an additional space configured to store and process a parity bit is included in the stacked core dies 100 to process the parity bit, the size of the core dies is increased and data processing speed is also reduced.

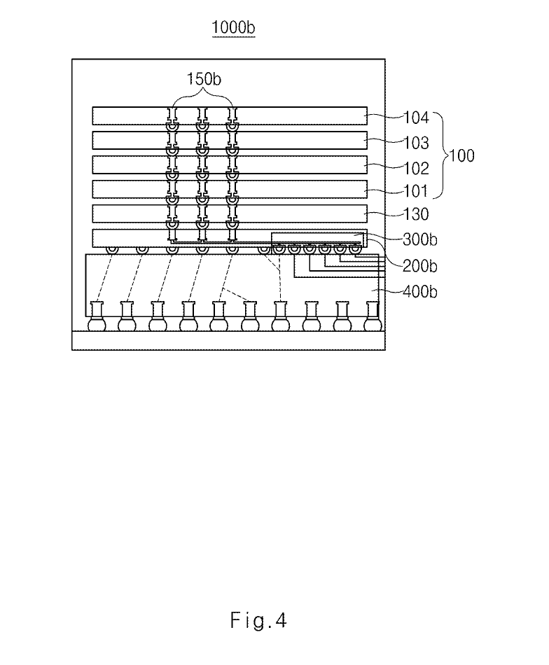

Therefore, system 10 according to an embodiment of the present invention may include an error correction unit in a separate die to perform an error correction operation on data written to or read from the stacked core dies 100. The separate die configured to process the parity bit may correspond to the logic die 200 including a logic processor. In another embodiment, the separate die may correspond to a parity die (see 130 of FIG. 4) configured to perform error correction operations.

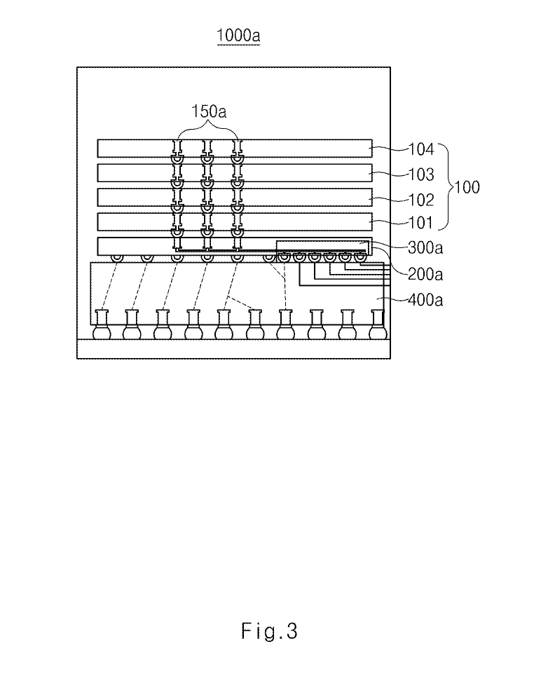

FIG. 3 and FIG. 4 illustrate a configuration of a memory device according to embodiments of the present invention with reference to a portion of FIG. 2 indicated by a dotted line will be described.

FIG. 3 is a cross-sectional view illustrating a memory device according to an embodiment of the present invention.

Referring to FIG. 3, the memory device 1000a may include a substrate 400a, a logic die 200a, a first interface unit 300a, and stacked core dies 100 including a plurality of core dies 101, 102, 103, and 104. As described above, the stacked core dies 100 are electrically coupled to the logic die 200a through a through via 150a.

FIG. 3 illustrates an embodiment in which a circuit configured to perform an error correction operation is provided in the logic die 200a.

In a read operation, data stored in the stacked core dies 100 is provided to the logic die 200a through the through via 150a. The logic die 200a performs an error correction operation by using a parity bit that was stored during a write operation. The logic die 200a determines whether or not the read data is erroneous using the parity bit, and repeats the data read operation or performs a separate operation for error correction when the error is generated. Both of these activities—active correction of data and repeating a read operation—are error correction operations. Data that is read and processed according to an error correction operation may be referred to as error-corrected data. Error-corrected data is provided to the central processing device 500 through a timing synchronization and interfacing operation.

In the related art, both data and parity bits are stored in the stacked core die 100, data and parity bits are read out from the stacked core die 100. Data errors are determined based on the read information, and no parity bit is provided to the logic die 200a. Therefore, in addition to a circuit configured to store data in the stacked core dies 100, a circuit configured to store the parity bit and a circuit configured to determine data errors are both within the same die. Accordingly, it is difficult to reduce sizes of stacked core dies and to correct an error generated in a process of providing read data through the through via 150a.

A memory device 1000a according to an embodiment of the present invention reads M/4-bit data from each of the core dies 101, 102, 103, and 104 when the logic die 200a provides M-bit data to the central processing device 500 in a single operation. The logic die 200a reads out p parity bits corresponding to the M-bit data from a memory in which the parity bits have been stored with respect to the M-bit data. For example, the p bits may correspond to the least number of bits in which error correction for the M bits may be performed.

The logic die 200a provides only M′-bit data in which an error correction operation is performed on the M bits to the central processing device 500.

In another embodiment, the logic die 200a may store the parity bits while error determination and error processing are performed in the central processing device 500. Therefore, the logic die 200a may provide (M+p)-bit data, in which the M-bit data read from the stacked core dies 100 and the p parity bits stored in the logic die 200a are added, to the central processing device 500. In an embodiment, p may be one or more bit for each associated block of data.

In a write operation, data provided from the central processing device 500 is received in the logic die 200a through the first interface unit 300a. The logic die 200a may generate error correction information including a parity bit with respect to the received data, the parity bit may be stored in the logic die 200a, and data may be written in a designated address of the stacked core dies 100. The parity bit stored in the logic die 200a may include information relating each parity bit to associated data. In another embodiment, an address in which the parity bit is stored may be stored in a location corresponding to an address in which real data is written.

In an embodiment, when data is provided from the central processing device 500, data to which the parity bit is added may be provided to the logic die 200a. The logic die 200a may store the received parity bit but not the data, and provide the data to the stacked core dies 100 for storage.

Timing synchronization performed when the logic die 200a transmits and receives data to and from the central processing device 500 may be performed in the first interface unit 300. In another embodiment, the timing synchronization may be performed in the second interface unit 350 included in the central processing device 500.

Since the logic die 200a is not used for data storage, an associated circuit area may be relatively small compared to a die which includes substantial logic operations and data storage. However, in an embodiment in which the logic die 200a is located below or between the stacked core dies 100, the logic die may be implemented in a size equal to or larger than that of at least the stacked core dies 100. Therefore, more space for performing error correction within the logic die 200a is available than conventional structures.

FIG. 4 is a cross-sectional view illustrating a memory device according to an embodiment of the present invention.

Referring to FIG. 4, the memory device 1000b may include a substrate 400b, a logic die 200b, a first interface unit 300b, a parity die 130, and a stacked core dies 100.

In the embodiment of FIG. 4, a function to determine whether or not data is erroneous by adding a parity bit to data or reading a parity bit corresponding to the read data may be implemented in the parity die 130.

Although FIG. 4 illustrates that the parity die 130 is disposed below the stacked core dies 100 and over the logic die 200b, the location of the parity die 130 is not limited thereto, and the parity die 130 may be located above the stacked core dies 100 or located between the core dies of the stacked core dies 100.

The stacked core dies 100, the parity die 130, and the logic die 200b may be electrically coupled to each other through a through via 150b.

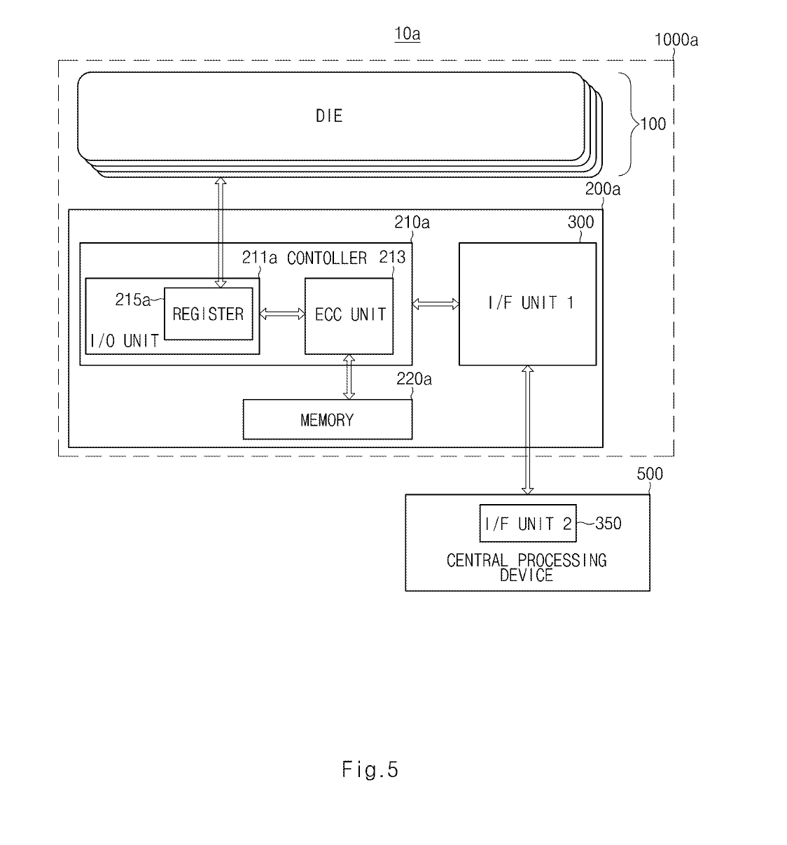

An error correction method according to an embodiment of the present invention will be described in detail with reference to FIG. 5.

FIG. 5 is a block diagram conceptually illustrating a system 10a including the memory device 1000a according to an embodiment of the present invention described with reference to FIG. 3.

FIG. 5 illustrates an embodiment in which a circuit configured to process a parity bit in which a memory configured to store a parity bit and error manage circuitry configured to determine whether or not data is erroneous through the parity bit are implemented in the inside of the logic die 200a.

Referring to FIG. 5, the system 10a may include stacked core dies 100, a logic die 200a, a first interface unit 300 in the logic die 200a, a central processing device 500, and a second interface unit 350 in the central processing device 500.

A controller 210a and a memory 220a are included in the logic die 200a. The controller 210a may include an input/output unit 211a and an error correction unit 213. In an embodiment, the input/output unit 211a may include a register 215a configured to temporarily store data.

First, a write operation of the system 10a will be described.

The first interface unit 300 receives data to be written in the stacked core dies 100 from the second interface unit 350 of the central processing device 500 in synchronization with respect to time. The first interface unit 300 performs an interfacing operation for converting the received data into data suitable for signal processing in the logic die 200a. Before the data is received, the logic die 200a may already receive a write command for operating a write operation from the central processing device 500.

The controller 210a receives data to be written, an address to which the data is to be written, and the like, and the error correction unit 213 adds a parity bit for error correction to the data. The parity bit added to the data may be stored in the memory 220a. As described above, since the parity bit is separated from the data and stored in a separate location, the parity bit may be stored along with information indicating an address of associated data in the memory 220a. In another embodiment, the storage location of the parity bits may correspond to storage locations of associated data. The input/output unit 211a may allow data to be temporarily stored in the register 215a, and allow the data to be written in the stacked core dies 100 based on operation timing.

The memory device 1000a according to an embodiment of the present invention may perform a burst operation which writes a plurality of pieces of data at once, or outputs pieces of read data at once according to the operation timing. In another embodiment, the memory device 1000a may temporarily store data of a variety of bits and then write the stored data.

Therefore, the data temporarily stored in the register 215a may be written in a designated location of a designated core die of the stacked core dies 100 according to control of the input/output unit 211a. The location in which the data is written may be determined according to an address provided from the central processing device 500.

In a memory device 1000a according to an embodiment of the present invention, processing the parity bit is performed not in the stacked core dies 100 but in the logic die 200a. Since the logic die 200a does not store the data but performs a logic operation and data transmission and reception, the logic die 200a may ensure an available space as compared to the core dies. Therefore, a size of the stacked core dies 100 can be reduced by performing an error correction operation using the parity bit, and storing the parity bit in the logic die 200a.

Since data is written in the stacked core dies 100 after a certain period of time, an operation of adding and storing a parity bit is performed on another data during a period of time when the data is temporarily stored in the register 211a, and thus increase in operation time due to an error correction operation can be minimized.

Error correction codes such as parity bits and cyclic redundancy codes (CRC) are used in generally-known error connection methods, and thus a detailed description of these methods will be omitted.

Next, a read operation of the system 10a according to an embodiment of the present invention will be described.

When a command for reading out data from a predetermined location of the stacked core dies 100 is received from the central processing device 500, the input/output unit 211a of the controller 210a may read out data from the predetermined location of the stacked core dies 100, and temporarily store the read data in the register 215a. A parity bit is read out from the memory 220a corresponding to an address of the stacked core dies 100 from which the data is read out. The logic die 200a may be in a state in which a signal for performing a read command is previously received from the central processing device 500.

In an embodiment, the error correction unit 213 determines whether or not data is erroneous based on the data and the parity bit, and provides error-corrected data to the first interface unit 300. The first interface unit 300 may transmit the data in timing synchronization with the second interface unit 350.

The central processing device 500 may perform various operations based on the read data.

The system 10a according to an embodiment of the present invention reads out data from each core die of the stacked core dies 100, and determines whether or not the data is erroneous with the parity bit stored in the logic die 200a in the read operation.

Since the stacked core dies 100 merely read out the data written in the memory and directly provide the read data to the logic die 200a, read speed is increased. There may be a waiting time for timing synchronization in the logic die 200 when the data is provided to the central processing device 500, and since an error correction operation may be performed during the waiting time, total operation time characteristics can be improved.

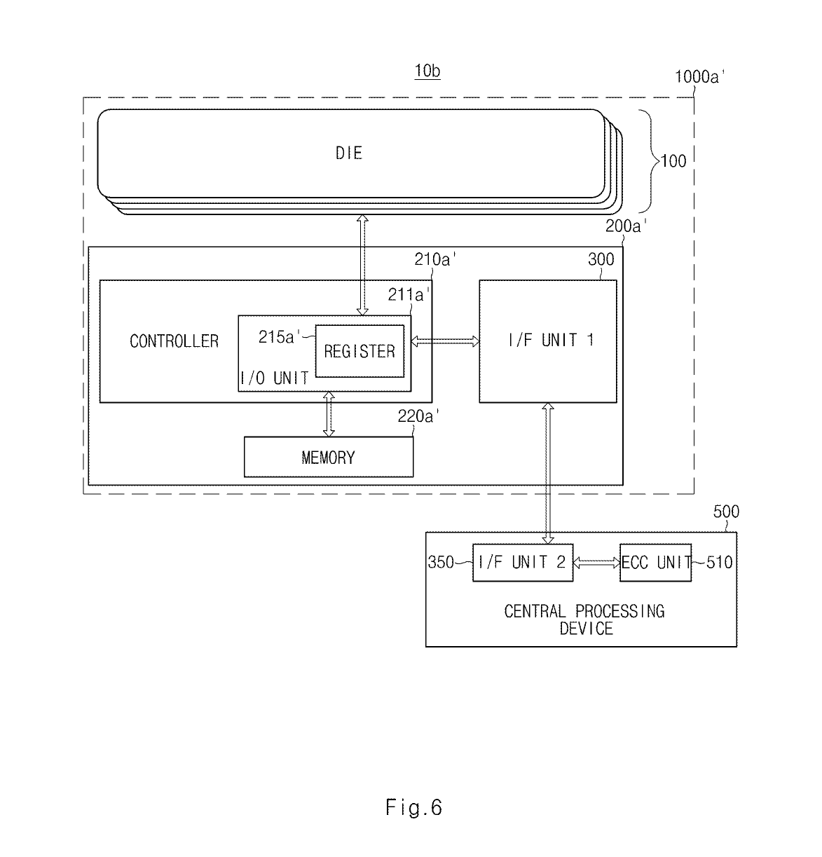

FIG. 6 is a block diagram illustrating another embodiment of a system including the memory device described in FIG. 3.

within contrast to the system 10a of FIG. 5, in a system 10b of FIG. 6, an error correction unit 510 configured to perform error correction on data is included in a central processing device 500, and the logic die 200a′ includes a memory 220a′ configured to store parity bits.

When the logic die 200a′ outputs a parity bit corresponding to data read out from stacked core dies 100 and provides the parity bit to the central processing device 500 or the logic die 200a′ writes data in the stacked core dies 100, the logic die 200a′ stores a parity bit provided from the central processing device 500. In addition, determination of the presence of errors in the data and determination of the parity bit added to the data is performed in the central processing device 500.

A read operation and a write operation of the system 10b of FIG. 6 will now be described.

In a write operation, the central processing device 500 may provide a write command to the memory device 1000a′. The central processing device 500 may provide the write command together with data to be written and an address to the memory device 1000a′. In an embodiment, after the central processing device 500 provides the write command to the memory device 1000a′, the central processing device 500 may transmit the data to be written and the address to the memory device 1000a′ after a predetermined period of time elapses. In the system 10b according to an embodiment of the present invention, the central processing device 500 generates a parity bit corresponding to the data, and provides the parity bit to the memory device 1000a′.

The input/output unit 211a′ of the memory device 1000a′ temporarily stores the data and the parity bit received from the central processing device 500 in the register 215a′.

The controller 210a′ allows the parity bit to be stored in a specific location in the memory 220a′ and data to be written in the stacked core dies 100 based on an address in which the data is to be written.

In a read operation, the central processing device 500 may transmit a read command together with an address from which data is to be read out to the memory device 1000a′. In an embodiment, after the central processing device 500 transmits the read command to the memory device 1000a′, the central processing device 500 may transmit the read address to the memory device 1000a′ after a predetermined period of time elapsed.

The input/output unit 211a′ of the memory device 1000a′ reads out data from the stacked core dies 100 based on the address received from the central processing device 500, reads a parity bit from the memory 220a′, and provides the read address and parity bit to the first interface unit 300. The central processing device 500 receives the data and the parity bit through the first interface unit 300 and the second interface unit 350. The central processing device 500 determines whether or not the received data is erroneous to perform the read operation again or to generate error-corrected data.

The memory device 1000a′ according to an embodiment of the present invention stores the parity bit and does not perform error correction, but does perform general data input/output operations. Because error correction circuits are not included on the stacked core dies 100 and the logic die 200a′, the stacked core dies 100 and the logic die 200a′ can be implemented in a small size, and the central processing device 500 can perform error correction to ensure data reliability.

The error correction unit 510 may perform error correction based on the received data and parity bit and discard the parity bit after error correction so that the central processing device 500 can process error-corrected data without the parity bit.

The system 10b of FIG. 6 may be used to increase data reliability with respect to chip dies which are implemented without error correction capability since an error correction circuit is not provided in the stacked core dies 100 or the logic die 200a′.

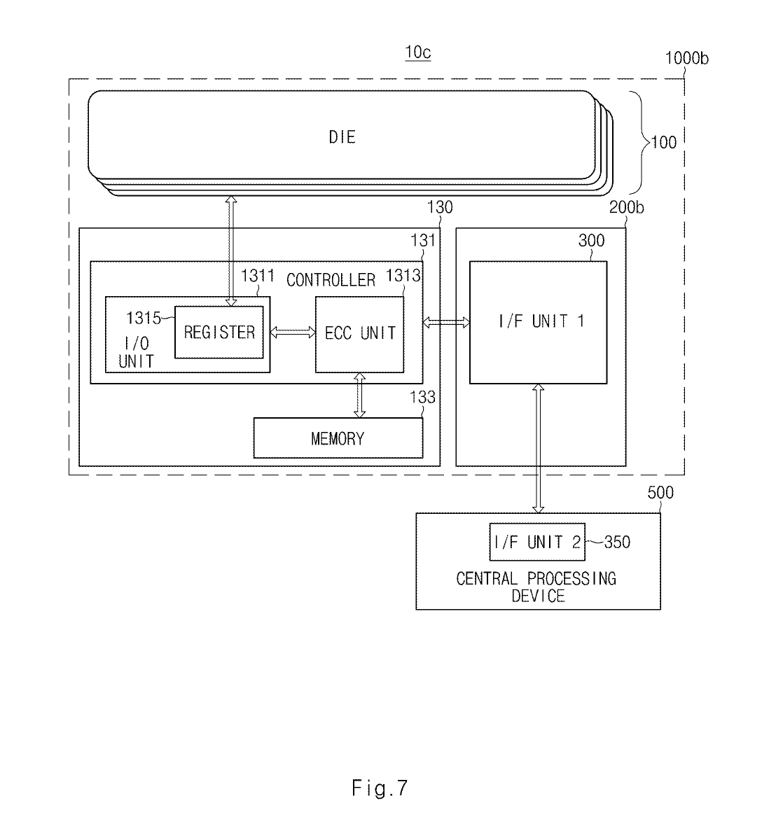

FIG. 7 is a block diagram illustrating a system 10c including the memory device 1000b of FIG. 4.

In FIG. 7, a separate parity die 130 configured to perform an error correction operation is provided. Data that has been error-corrected in the parity die 130 is provided to a central processing device 500 via a first interface unit 300 in a logic die 200b through a through via (150b of FIG. 4).

The memory device 1000b of FIG. 7 is different from the memory device 1000a of FIG. 5 and the memory device 1000a′ of FIG. 6 in that a controller 131 and a memory 133 are provided not in the parity die 130 instead of the logic die 200b.

The controller 131 may include an input/output unit 1311 and an error correction unit 1313, and in an embodiment, the input/output unit 1311 may include a register 1315. Operation of the controller 131 are substantially the same as operation of the controller 210a included in the memory device 1000a of FIG. 5, and the form and function of the memory 133 are substantially the same as the memory 220a of FIG. 5.

However, in the system 10c of FIG. 7, an interfacing operation is performed in the first interface unit 300 included in the logic die 200b. Therefore, the logic die 200b receives data which is subjected to error correction from the parity controller 131 of the parity die 130, and provides error-corrected data to the second interface unit 350 of the central processing device 500 in a time synchronized transmission.

The controller 131 of the parity die 130 may receive data from the central processing device 500, and provide the data to stacked core dies 100 after adding a parity bit to the data.

As described above, in embodiments of the present invention, error correction circuitry is not included in the stacked core dies 100. Rather, error correction circuitry may be located in a separate logic die 200a, or shared between a logic die 200a′ and a central processing device 500. Parity bits associated with blocks of data stored in the stacked core dies may be stored in the logic die 200a. When error correction logic is disposed on the logic die, parity bits are not transmitted to the central processing device 500, but when error correction logic is disposed in the central processing device 500, parity bits stored in the logic die 200a′ are transmitted to the central processing device 500 along with the data. Because error correction circuitry and storage for parity bits are not included in the stacked core dies 100, fabrication of the stacked core dies 100 is simplified and the stacked core dies can have a smaller size.

The system 10 according to an embodiment of the present invention can include the plurality of stacked core dies 100, and thus a total size of the system 10 can be minimized when a size of each core die is reduced.

In the systems 10, 10a, 10b, and 10c according to embodiments of the present invention, the stacked core dies 100 may include a memory cell array including a dynamic random access memory (DRAM) device, and a wide I/O may be implemented by stacking a plurality of core dies and electrically coupling the core dies using the through vias.

Further, the memory devices 1000, 1000a, 1000a′, and 1000b may be implemented as a high bandwidth memory (HBM) in some embodiments.

A memory device and a system including the same according to embodiments of the present invention can implement high speed data input/output operations and ensure reliability of data.

Further, a memory device and a system including the same according to embodiments can change an error correction method to ensure design flexibility without change in a configuration of the core dies.

A memory device and system according to embodiments can include a separate die disposed below or above a plurality of stacked memory dies and configured to perform an error correction function to reduce sizes of the memory dies and simultaneously improve speed of error correction.

A memory device and system according to embodiments can change an error correction method to obtain design flexibility without change in structures of the memory dies.

The above embodiments of the present invention are illustrative and not limitative. Various alternatives and equivalents are possible. The invention is not limited by the embodiment described herein. Nor is the invention limited to any specific type of semiconductor device. Other additions, subtractions, or modifications are obvious in view of the present disclosure and are intended to fall within the scope of the appended claims.

What is claimed is:

1. A memory device comprising:
a plurality of first dies stacked on a substrate; and
a second die configured to perform error correction on write data written to the first dies and read data read out from the plurality of first dies.

2. The memory device of claim 1, wherein the second die includes:
a memory configured to store an error correction code for checking whether or not the read data includes an error; and
a controller configured to generate the error correction code based on the write data and store the error correction code in the memory and to read out the error correction code corresponding to the read data from the memory and check whether or not the read data is erroneous.

3. The memory device of claim 2, wherein the controller includes:
an input/output unit configured to read out the read data from the first stacked dies and read out the error correction code from the memory, based on a read command and a read address provided from an exterior, and to write the write data based on a write command, the write data, and a write address, and write the error correction code generated based on the write data in the memory; and
an error correction unit configured to check whether or not the read data is erroneous based on the read error correction code, and generate the error correction code based on the write data.

4. The memory device of claim 1, wherein the second die is a logic die including control logic circuitry.

5. The memory device of claim 1, wherein the second die is a parity die configured to perform the error correction.

6. The memory device of claim 5, further comprising a logic die stacked below the plurality of first dies and configured to perform logic operations for data exchanged between the first dies and a central processing device.

7. The memory device of claim 4 wherein the logic die is disposed between the second die and the substrate.

8. The memory device of claim 1, wherein the plurality of first dies include dynamic random access memory (DRAM) devices.

9. The memory device of claim 1, wherein the plurality of first dies are electrically coupled to one another through at least one through via.

10. The memory device of claim 1, wherein the second die includes an interface unit configured to perform an interfacing operation on at least one of a control signal, data stored in the plurality of first dies, an update signal, a status signal, and a training signal.

11. A system comprising:
a central processing device configured to provide an operation command; and
a memory device configured to receive the operation command from the central processing device through a channel to perform a read operation and a write operation, and perform an error correction operation in the read and write operations,
wherein the memory device includes:
a plurality of first dies stacked on a substrate; and
a second die configured to perform an error correction operation on write data written in the first dies and read data read out from the first dies.

12. The system of claim 11, wherein the central processing device and the memory device are mounted on the substrate.

13. The system of claim 11, wherein the channel is coupled between an interface unit included in the second die and an interface unit included in the central processing device.

14. The system of claim 13, wherein the interface units are physical control interfaces.

15. The system of claim 11, wherein the central processing device includes a graphic processing unit (GPU) or a central processing unit (CPU).

16. The system of claim 11, further comprising:
a plurality of the memory devices disposed on the substrate around the central processing device.

17. A semiconductor device, comprising:
a substrate;
a plurality of memory dies and a second die stacked on the substrate;
a central processing device in communication with the memory dies through the second die; and
a memory disposed on the second die, the memory storing error correction information associated with data stored in the plurality of memory dies.

18. The semiconductor device of claim 17, wherein the second die is a logic die including a controller circuit with a register temporarily storing data exchanged between the plurality of memory dies and the central processing device.

19. The semiconductor device of claim 17, further comprising:
a logic die stacked with the plurality of memory dies and the second die.

20. The semiconductor device of claim 17, wherein error correction is performed during a waiting time in a time cycle synchronized between an interface unit and the central processing device.
